(19) United States
(12) Patent Application Publication
(10) Pub. No.: US 2015/0084653 A1
(43) Pub. Date: Mar. 26, 2015

(54) CURRENT SOURCE DRIVEN MEASUREMENT AND MODELING

(71) Applicant: QUALCOMM Incorporated, San Diego, CA (US)

(72) Inventors: Young K. Song, San Diego, CA (US); Kyu-Pyung Hwang, San Diego, CA (US); Dong Wook Kim, San Diego, CA (US); Changhan Hobie Yun, San Diego, CA (US)

(73) Assignee: QUALCOMM Incorporated, San Diego, CA (US)

(21) Appl. No.: 14/038,608

(22) Filed: Sep. 26, 2013

(51) Int. Cl. G01R 27/02; G01R 31/28

(52) U.S. Cl. CPC G01R 27/02; G01R 31/2851
USPC 324/713

(57) ABSTRACT

A method and apparatus for testing integrated circuit resistors includes applying a variable source current to a resistive device under test (DUT), measuring the resistance of the resistive DUT as a function of the source current, and fitting the measured resistance to parameters of a polynomial parametric equation, wherein the parametric equation comprises a constant resistance at zero current bias plus a second order current coefficient of resistance multiplied by the square of the current.

### BACKGROUND

1. Field

The present disclosure relates generally to integrated circuit testing and modeling.

2. Background

Traditionally, Silicon (Si) integrated circuit resistor elements have been measured using a voltage source to model the resistor as a body element resistance and two end resistors. Resistance of the body element is conventionally modeled as a function of sheet resistance (Rsh), voltage, sheet width W, sheet length L, voltage, and temperature: R=f (Rsh, V, W, L, T).

This multi-variable dependence may result in a non-constant, non-linear value of resistance with applied voltage.

In high volume manufacturing (HVM) Si fabrication, such as integrated circuits for wireless communication systems, monitoring of doping level and built-in Kelvin 4-point test structures is one of several conventional testing procedures and methods involving voltage source driven measurement. Data driven process modeling and characterization typically involve calculations using transcendental functions with many variables for curve fitting (e.g., TSMC© cmosp18.5.2 [Resistor]). This approach to characterization may adversely increase testing time and may also affect modeling accuracy.

There is a need, therefore, for an approach to measurement, characterization and modeling of resistive components in integrated circuits that reduces testing time and improves modeling accuracy.

### SUMMARY

In an embodiment of the disclosure, a method of testing integrated circuit resistors includes applying a variable source current to a resistive device under test (DUT), measuring the resistance of the resistive DUT as a function of the source current, and fitting the measured resistance to parameters of a polynomial parametric equation, wherein the parametric equation comprises a constant resistance at zero current bias plus a second order current coefficient of resistance times the square of the current.

In an embodiment of the disclosure, an apparatus for testing integrated circuit resistors includes a variable current source coupled to a resistive device under test (DUT), a resistance measuring device to measure the resistance of the resistive DUT as a function of the source current, and a parameter fitting device to determine coefficients of a polynomial parametric equation corresponding to the resistance of the resistive DUT as a function of current, wherein the parametric equation comprises a constant resistance at zero current bias plus a second order current coefficient of resistance times the square of the current.

In an embodiment of the disclosure, a transitory computer readable media containing instructions which when executed by a processor cause the processor to perform the following steps of applying a variable source current to a resistive device under test (DUT), measuring the resistance of the resistive DUT as a function of the source current, and fitting the measured resistance to parameters of a polynomial parametric equation, wherein the parametric equation comprises a constant resistance at zero current bias plus a second order current coefficient of resistance multiplied by the square of the current.

In an embodiment of the disclosure, an apparatus for testing integrated circuit resistors includes a variable current source coupled to a resistive device under test (DUT), means to measure the resistance of the resistive DUT as a function of the source current, means to determine coefficients of a polynomial parametric equation corresponding to the resistance of the resistive DUT as a function of current, wherein the parametric equation comprises a constant resistance at zero current bias added to a second order current coefficient of resistance multiplied by the square of the current.

### BRIEF DESCRIPTION OF THE DRAWINGS

FIG. 1 illustrates a wireless communication system, in accordance with certain embodiments of the disclosure.

FIG. 2 illustrates a simplified model of a poly-silicon resistor in accordance with an embodiment of the disclosure.

FIG. 3 illustrates an equivalent circuit model of the poly-silicon resistor of FIG. 1.

FIG. 4 illustrates a voltage source measurement configuration, in accordance with an embodiment of the disclosure.

FIG. 5 illustrates a current source test configuration, in accordance with an embodiment of the disclosure.

FIG. 6 illustrates an equivalent circuit model of the poly-silicon resistor of FIG. 5, in accordance with an embodiment of the disclosure.

FIG. 7 is a flow chart of the steps in a method of measurement of device resistance using a current driven source, in accordance with an embodiment of the disclosure.

### DETAILED DESCRIPTION

Various aspects are now described with reference to the drawings. In the following description, for purposes of explanation, numerous specific details are set forth in order to provide a thorough understanding of one or more aspects. However, it may be evident that such aspect(s) may be practiced without these specific details.

As used in this application, the terms “component,” “module,” “system” and the like are intended to include a computer-related entity, such as, but not limited to hardware, firmware, a combination of hardware and software, software, or software in execution. For example, a component may be, but is not limited to being, a process running on a processor, a processor, an object, an executable, a thread of execution, a program and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets, such as data from one component interacting with another component in a local system, distributed system, and/or across a network such as the Internet with other systems by way of the signal.

As used herein, the term “determining” encompasses a wide variety of actions and therefore, “determining” can include calculating, computing, processing, deriving, investigating, looking up (e.g., looking up in a table, a database or another data structure), ascertaining and the like. Also, “determining” can include resolving, selecting choosing, establishing, and the like.

The phrase “based on” does not mean “based only on,” unless expressly specified otherwise. In other words, the phrase “based on” describes both “based only on” and “based at least on.”

Moreover, the term “or” is intended to man an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

The various illustrative logical blocks, modules, and circuits described in connection with the present disclosure may be implemented or performed with a general purpose processor, a digital signal processor (DSP), an application specific integrated circuit (ASIC), a field programmable gate array (FPGA), or other programmable logic device, discrete gate or transistor logic, discrete hardware components or any combination thereof designed to perform the functions described herein. A general purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core or any other such configuration.

The steps of a method or algorithm described in connection with the present disclosure may be embodied directly in hardware, in a software module executed by a processor or in a combination of the two. A software module may reside in any form of storage medium that is known in the art. Some examples of storage media that may be used include RAM memory, flash memory, ROM memory, EPROM memory, EEPROM memory, registers, a hard disk, a removable disk, a CD-ROM, and so forth. A software module may comprise a single instruction, or many instructions, and may be distributed over several different code segments, among different programs and across multiple storage media. A storage medium may be coupled to a processor such that the processor can read information from, and write information to, the storage medium. In the alternative, the storage medium may be integral to the processor.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in software, the functions may be stored as one or more instructions on a computer-readable medium. A computer-readable medium may be any available medium that can be accessed by a computer. By way of example, and not limitation, a computer-readable medium may comprise RAM, ROM, EEPROM, CD-ROM or other optical disk storage, magnetic disk storage, or other magnetic storage devices, or any other medium that can be used to carry or store desired program code in the form of instructions or data structures and that can be accessed by a computer. Disk and disc, as used herein, includes compact disk (CD), laser disk, optical disc, digital versatile disk (DVD), floppy disk, and Blu-ray® disc where disks usually reproduce data magnetically, while discs reproduce data optically with lasers.

Software or instructions may also be transmitted over a transmission medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of transmission medium.

Further, it should be appreciated that modules and/or other appropriate means for performing the methods and techniques described herein can be downloaded and/or otherwise obtained by a mobile device and/or base station as applicable. For example, such a device can be coupled to a server to facilitate the transfer of means for performing the methods described herein. Alternatively, various methods described herein can be provided via a storage means (e.g., random access memory (RAM), read only memory (ROM), a physical storage medium such as a compact disc (CD) or floppy disk, etc.), such that a mobile device and/or base station can obtain the various methods upon coupling or providing the storage means to the device. Moreover, any other suitable technique for providing the methods and techniques described herein to a device can be utilized.

Furthermore, various aspects are described herein in connection with a terminal, which can be a wired terminal or a wireless terminal. A terminal can also be called a system, device, subscriber unit, subscriber station, mobile station, mobile, mobile device, remote station, remote terminal, access terminal, user terminal, communication device, user agent, user device, or user equipment (UE). A wireless terminal may be a cellular telephone, a satellite phone, a cordless telephone, a Session Initiation Protocol (SIP) phone, a wireless local loop (WLL) station, a personal digital assistant (PDA), a handheld device having wireless connection capability, a computing device, or other processing devices connected to a wireless modem. Moreover, various aspects are described herein in connection with a base station. A base station may be utilized for communicating with wireless terminal(s) and may also be referred to as an access point, a Node B, or some other terminology.

The techniques described herein may be used for characterization and modeling of devices used in various wireless communication networks such as Code Division Multiple Access (CDMA) networks, Time Division Multiple Access (TDMA) networks, Frequency Division Multiple Access (FDMA) networks, Orthogonal FDMA (OFDMA) networks, Single-Carrier FDMA (SC-FDMA) networks, etc. The terms “networks” and “systems” are often used interchangeably. A CDMA network may implement a radio technology such as Universal Terrestrial Radio Access (UTRA), CDMA2000, etc. UTRA includes Wideband CDMA (W-CDMA). CDMA2000 covers IS-2000, IS-95 and technology such as Global System for Mobile Communication (GSM).

An OFDMA network may implement a radio technology such as Evolved UTRA (E-UTRA), the Institute of Electrical and Electronics Engineers (IEEE) 802.11, IEEE 802.16, IEEE 802.20, Flash-OFDAM®, etc. UTRA, E-UTRA, and GSM are part of Universal Mobile Telecommunication System (UMTS). Long Term Evolution (LTE) is a release of UMTS that uses E-UTRA. UTRA, E-UTRA, GSM, UMTS, and LTE are described in documents from an organization named “3^{rd} Generation Partnership Project” (3GPP). CDMA2000 is described in documents from an organization named “3^{rd} Generation Partnership Project 2” (3GPP2). These various radio technologies and standards are known in the art. For clarity, certain aspects of the techniques are described below for LTE, and LTE terminology is used in much of the description below. It should be noted that the LTE terminology is used by way of illustration and the scope of the disclosure is not limited to LTE. Rather, the techniques described herein may be utilized in various application involving wireless transmissions, such as personal area networks (PANs), body area networks (BANs), location, Bluetooth, GPS, UWB, RFID, and the like. Further, the techniques may also be utilized in wired systems, such as cable modems, fiber-based systems, and the like.

Single carrier frequency division multiple access (SC-FDMA), which utilizes single carrier modulation and frequency domain equalization has similar performance and essentially the same overall complexity as those of an OFDMA system. SC-FDMA signal may have lower peak-to-average power ration (PAPR) because of its inherent single carrier structure. SC-FDMA may be used in the uplink communications where the lower PAPR greatly benefits the mobile terminal in terms of transmit power efficiency.

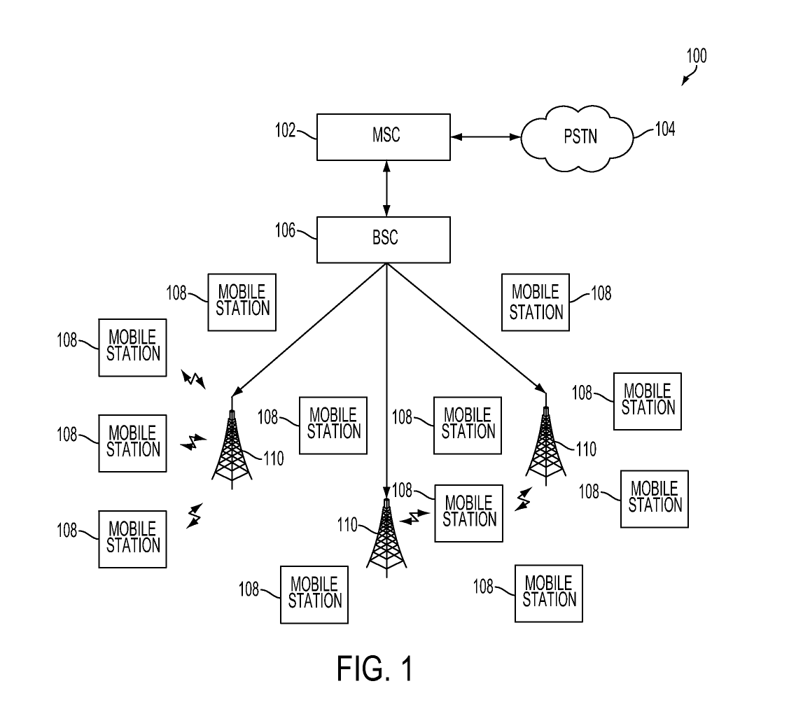

FIG. 1 illustrates a wireless system 100 that may include a plurality of mobile stations 108, a plurality of base stations 110, a base station controller (BSC) 106, and a mobile switching center (MSC) 102. The system 100 may be GSM, EDGE, WCDMA, CDMA, etc. The MSC 102 may be configured to interface with a public switched telephone network (PTSN) 104. The MSC may also be configured to interface with the BSC 106. There may be more than one BSC 106 in the system 100. Each base station 110 may include at least one sector, where each sector may have an omni-directional antenna or an antenna pointed in a particular radial direction away from the base stations 110. Alternatively, each sector may include two antennas for diversity reception. Each base station 110 may be designed to support a plurality of frequency assignments. The intersection of a sector and a frequency assignment may be referred to as a channel. The mobile stations 108 may include cellular or portable communication system (PCS) telephones.

During operation of the cellular telephone system 100, the base stations 110 may receive sets of reverse link signals from sets of mobile stations 108. The mobile stations 108 may be involved in telephone calls or other communications. Each reverse link signal received by a given base station 110 may be processed within that base station 110. The resulting data may be forwarded to the BSC 106. The BSC 106 may provide call resource allocation and mobility management functionality including the orchestration of soft handoffs between base stations 110. The BSC 106 may also route the received data to the MSC 102, which provides additional routing services for interfacing with the PSTN 104. Similarly, the PTSN 104 may interface with the MSC 102, and the MSC 012 may interface with the BSC 106, which in turn may control the base stations 110 to transmit sets of forward link signals to sets of mobile stations 108.

A method is disclosed that may reduce testing time and also improve characterization accuracy for resistors in integrated circuits, such as may be found in wireless telecommunication systems. However, the method may be found useful in all manner of systems including integrated circuits and should not be interpreted as being applicable solely to wireless telecommunication systems. The method is based on current source driven measurement instead of the conventional voltage source driven measurement widely used by fabrication suppliers. Si-wafer test fixtures used in the disclosed method are different from conventional fixtures used in testing based on voltage source driven measurements. Software algorithms used with testing equipment for the disclosed method are also different because the proposed method involves simpler equations and a reduced number of variables to be fitted. The variable consist of zero and first order coefficients of source current in one polynomial expression of current dependence and zero, first and second order and coefficients resistance coefficients of temperature in a second polynomial expression of temperature dependence. The coefficients are determined by linear regression of data obtained by measurements under various conditions of constant source current and/or temperature.

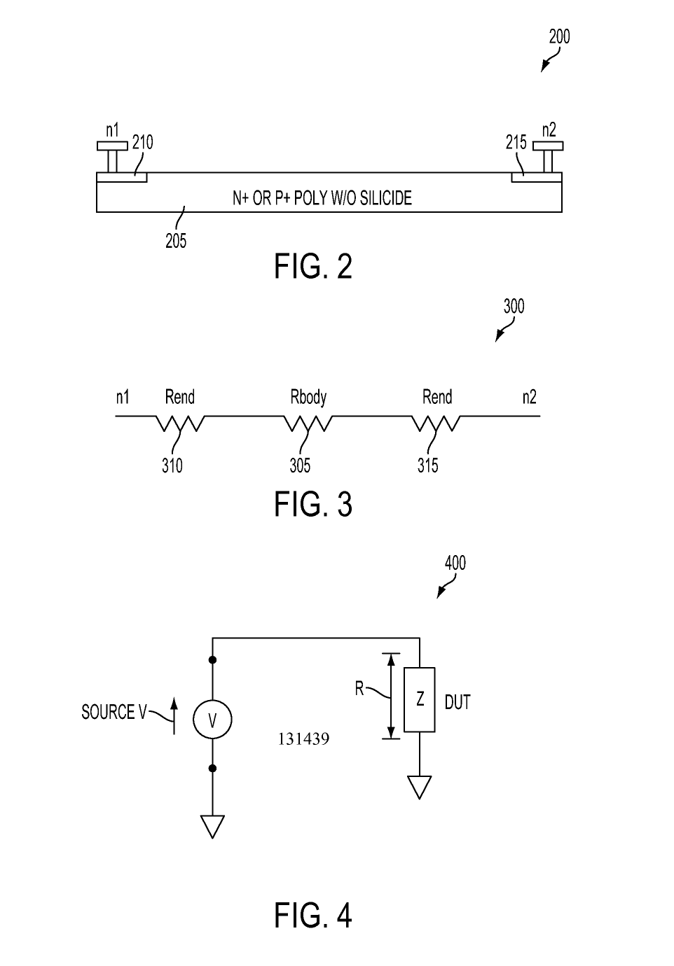

FIG. 2 illustrates a simplified model of a poly-silicon resistor 200 consisting of a body portion 205 and two end resistor elements 210, 215 that may be represented between two contacts n1 and n2. The corresponding simplified circuit model 300 may be represented as shown in FIG. 3. Rend 310, 315 represent the resistance of the respective contacts n1, and n2, which may be distinct and different, but are represented as identical for simplified purposes of illustration. n1 and n2 are contact points at which measurements are made. For each controlled set temperature and set source current, the resistance is measured between n1 and n2. Rend 310, 315 (assumed substantially identical at n1 and n2) are the two end resistor elements associated with the contacts n1 and n2. Rbody 305 is the resistance associated with the sheet resistance of the poly-silicon resistor on the Si surface. The total resistance R is given by:

R=2×Rend+Rbody

FIG. 4 shows a conventional voltage source measurement configuration 400, where R is the measured impedance Z of the device under test. Assuming that the two end resistor elements associated with contacts n1 and n2 have identical dimensions ΔW×ΔL, and the overall dimension of the resistor R is W×L, each end resistance may be represented by:

Rend=Rend0/(W−ΔW),

where Rend0 is the end resistance at zero current bias.

The resistance Rbody is given by:

Rbody=Rsh*(L−ΔL)/(W−ΔW)

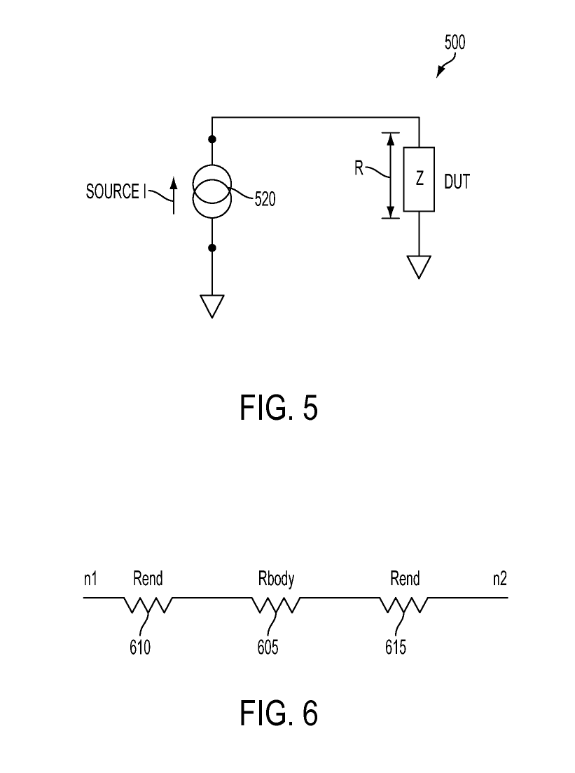

Determination of Rend and Rbody is conventionally done by parameter fitting to a complex set of transcendental equations, including dependency on applied voltage. Embodiments described herein provide a method based on current source measurement that may result in reduced testing requirements and fewer curve fitting parameters. FIG. 5 illustrates a current source test configuration 500. A current source 520 drives impedance element Z (the device under test (DUT)) whose resistance R is measured. Resistance of the body element is next modeled as a function of sheet resistance (Rsh), current I, sheet width W, sheet length L, and temperature T:

Rbody=f(Rsh,I,W,L,T),

where R is modeled as shown in FIG. 6, which includes two end resistances Rend 610, 615 and a body resistance Rbody 605.

In an aspect of the disclosure, the resistor value of an end or body part may be generally expressed as simple second order functions of current and temperature:

$$\begin{matrix}R = [ a \times {I}^{2} + r 0 ] \times [ 1 + TC 1 \times dT + TC 2 \times {( dT )}^{2} ] \\ = r 0 \times ( 1 + IC \times {I}^{2} ) \times [ 1 + TC 1 \times dT + TC 2 \times {( dT )}^{2} ] ,\end{matrix}$$

$$where$$

$$IC = a / r 0 , \\ and$$

$$R = 2 \times {R}_{end} + {R}_{body} ,$$

where IC is a second order coefficient of current dependence, r0 is the resistance at zero bias, TC1 is a first order coefficient of temperature dependence dT, and TC2 is a second order coefficient of temperature dependence.

More specifically, the body and end resistances 605, 610, 615 may be expressed as

R_{body}=[a_{body}×I²+r0_{body}]×[1+TC_{b1}×dT+TC_{b2}×(dT)²],

Rend=[a_{end}×I²+r0_{end}]×[1+TCₑ₁×dT+TCₑ₂×(dT)²],

where TC_{b} and TCₑ denote temperature coefficients of the body and end resistance elements, respectively, and the subscript numerics 1 and 2 denote first and second order temperature coefficients of the body and end resistances.

Testing and measurement may be conducted at constant temperature, which results in simplified modeling as the term dependent on temperature reduces to unity (i.e., dT=0). Thus, two coefficients, (a, r0) may be determined directly. Correspondingly, temperature measurements may be conducted at fixed drive current, resulting in parametric sets of data, from which all coefficients may be determined without resorting to curve fitting of transcendental functions (e.g., hyperbolic functions such as tan h).

It may be appreciated that the test fixture required in the current source based measurement may be a simplified two-point measurement based on a defined source current, as compared to the Kelvin-type 4-point resistance measurement technique based on a defined source voltage. It may be further appreciated that, because resistance is modeled as a second order parametric equation depending on current, that only two coefficients, i.e., zero and second order (r0 and a, respectively), may be extracted by linear regression, and does not include more complex parameter fitting calculation.

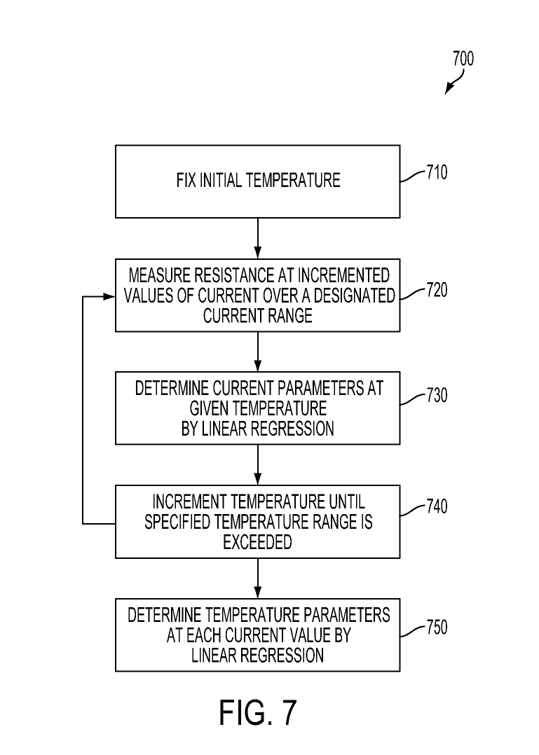

FIG. 7 is a flow chart of the steps in an embodiment of a method 700 of measurement of device resistance using a current driven source. In process block 710 the DUT is environmentally controlled to an initial reference temperature. The resistance of the DUT is measured in process block 720 for various values of the supplied source current, starting at zero, and incremented over a designated range. The current parameters (zero and first order) are determined in process block 730 linear regression analysis of the measurements. The temperature is incremented in process block 740, and the measurement process continues by returning to process block 720 to make resistance measurements versus source current until the full temperature range is covered, when the method continues at process block 740. When all temperature and current data is obtained, in process block 750 the zero, first and second order temperature parameters are determined from the measurements.

One of skill in the art will recognize that the order of steps may be organized in different ways and still represent the disclosed method of resistance characterization within the scope of the disclosure. For example, the source current may be fixed, and the temperature parameters determined for each current by collecting resistance measurements versus temperature, followed by an incrementing of the source current and repeating the resistance measurements versus temperature, after which the current parameters may be determined at each temperature from the measurements. Alternatively, measurements of resistance may be accumulated for ordered pairs of temperature and source current, and the accumulated data arranged to extract the parameters as described above. The parameters may be determined by linear regression analysis of the measured values of resistance versus current and temperature.

It is understood that the specific order or hierarchy of steps in the processes disclosed is an illustration of exemplary approaches. Based upon design preferences, it is understood that the specific order or hierarchy of steps in the processes may be rearranged. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

It is to be understood that the claims are not limited to the precise configuration and components illustrated above. Various modifications, changes and variations may be made in the arrangement, operation and details of the systems, methods, and apparatus described herein without departing from the scope of the claims.

What is claimed is:

1. A method of testing integrated circuit resistors comprising:
applying a variable source current to a resistive device under test (DUT);
measuring the resistance of the resistive DUT as a function of the source current; and
fitting the measured resistance to parameters of a polynomial parametric equation, wherein the parametric equation comprises a constant resistance at zero current bias plus a second order current coefficient of resistance times the square of the current.

2. The method of claim 1, further comprising determining the constant resistance at zero current and the second order current coefficient of resistance from the measurements by linear regression.

3. The method of claim 1, further comprising measuring the resistance as a function of the variable current at a constant temperature.

4. The method of claim 1, further comprising measuring the resistance at a constant current as a function of an applied variable temperature, wherein
the parametric equation further comprises a temperature dependency cofactor, the cofactor including a unity constant at a fixed reference temperature added to a first order temperature coefficient times a change in temperature added to a second order temperature coefficient multiplied by the square of the change in temperature.

5. The method of claim 4, further comprising determining the first order temperature coefficient and the second order temperature coefficient from the measurements by linear regression.

6. The method of claim 1, wherein the DUT comprises an equivalent circuit of two end resistive elements in series combination with a body resistance element, wherein the overall dimension of the resistive elements has a length L and a width W, and an area L×W.

7. The method of claim 6, wherein the body resistance element is a poly-silicon sheet resistor on a Si substrate.

8. The method of claim 7, wherein a resistance of the body resistance element is a function of a sheet resistance of the sheet, the source current, a width of the sheet layer, a length of the sheet layer, and temperature.

9. The method of claim 8 wherein, when the end resistive elements each have a sheet dimension area of ΔW×ΔL, the end resistive elements have a resistance Rend equal to an end resistance at zero source current bias R0 divided by (W−ΔW).

10. The method of claim 9, wherein the body resistance Rbody is equal to a body sheet resistance Rsh multiplied by (L−ΔL) and divided by (W−ΔW).

11. An apparatus for testing integrated circuit resistors comprising:
a variable current source coupled to a resistive device under test (DUT);
a resistance measuring device to measure the resistance of the resistive DUT as a function of the source current;
a parameter fitting device to determine coefficients of a polynomial parametric equation corresponding to the resistance of the resistive DUT as a function of current, wherein
the parametric equation comprises a constant resistance at zero current bias plus a second order current coefficient of resistance multiplied by the square of the current.

12. The apparatus of claim 11, wherein the parameter extraction device determines the constant resistance at zero current and the second order current coefficient of resistance from the measurements by linear regression.

13. The apparatus of claim 11, wherein the resistance measuring device is further configured to measure the resistance as a function of the variable current at a constant temperature.

14. The apparatus of claim 11, wherein the parametric equation further comprises a temperature dependency cofactor, the cofactor including a unity constant corresponding to a fixed reference temperature added to a first order temperature coefficient multiplied by a change in temperature plus a second order temperature coefficient times the square of the change in temperature.

15. The apparatus of claim 14, wherein the parameter extraction device is configured to determine the first order temperature coefficient and the second order temperature coefficient from the measurements by linear regression.

16. The apparatus of claim 11, wherein the resistive DUT comprises an equivalent circuit of two end elements in series combination with a body element, wherein the overall dimension of the resistive DUT has a length L, a width W, and an area L x W.

17. The apparatus of claim 16, wherein the body element of the resistive DUT is a poly-silicon sheet resistor on a Si substrate.

18. The apparatus of claim 17, wherein a resistance of the body element of the DUT is a function of a sheet resistance of the sheet, the source current, a width of the sheet layer, a length of the sheet layer, and temperature.

19. The apparatus of claim 18, wherein when the end elements each have a sheet dimension area of ΔW×ΔL, the end elements have a resistance Rend equal to an end resistance R0 at zero source current bias divided by (W−ΔW).

20. The apparatus of claim 19, wherein the body resistance is given by Rbody equal to a body sheet resistance Rsh multiplied by (L−ΔL) and divided by (W−ΔW).

21. A non-transitory computer readable media containing instructions which when executed by a processor cause the processor to perform the following steps:
applying a variable source current to a resistive device under test (DUT);
measuring the resistance of the resistive DUT as a function of the source current; and
fitting the measured resistance to parameters of a polynomial parametric equation, wherein the parametric equation comprises a constant resistance at zero current bias plus a second order current coefficient of resistance multiplied by the square of the current.

22. The non-transitory computer readable media of claim 21, further comprising determining the constant resistance at zero current and the second order current coefficient of resistance from the measurements by linear regression.

23. The non-transitory computer readable media of claim 21, further comprising measuring the resistance as a function of the variable current at a constant temperature.

24. The non-transitory computer readable media of claim 21, further comprising measuring the resistance at a constant current as a function of an applied variable temperature, wherein
the parametric equation further comprises a temperature dependency cofactor, the cofactor including a unity constant at a fixed reference temperature added to a first order temperature coefficient multiplied by a change in temperature added to a second order temperature coefficient multiplied by the square of the change in temperature.

25. The non-transitory computer readable media of claim 24, further comprising determining the first order temperature coefficient and the second order temperature coefficient from the measurements by linear regression.

26. The non-transitory computer readable media of claim 21, wherein the DUT comprises an equivalent circuit of two end resistive elements in series combination with a body resistance element, wherein the overall dimension of the resistive elements has a length L and a width W, and an area L×W.

27. The non-transitory computer readable media of claim 26, wherein the body resistance element is a poly-silicon sheet resistor on a Si substrate.

28. The non-transitory computer readable media of claim 27, wherein a resistance of the body resistance element is a function of a sheet resistance of the sheet, the source current, a width of the sheet layer, a length of the sheet layer, and temperature.

29. The non-transitory computer readable media of claim 28, wherein, when the end resistive elements each have a sheet dimension area of ΔW×ΔL, the end resistive elements have a resistance Rend equal to an end resistance at zero source current bias R0 divided by (W−ΔW).

30. The non-transitory computer readable media of claim 29, wherein the body resistance Rbody is equal to a body sheet resistance Rsh multiplied by (L−ΔL) and divided by (W−ΔW).

31. An apparatus for testing integrated circuit resistors comprising:
a variable current source coupled to a resistive device under test (DUT);
means to measure the resistance of the resistive DUT as a function of the source current;
means to determine coefficients of a polynomial parametric equation corresponding to the resistance of the resistive DUT as a function of current, wherein
the parametric equation comprises a constant resistance at zero current bias added to a second order current coefficient of resistance multiplied by the square of the current.

32. The apparatus of claim 31, wherein the coefficient determining means determines the constant resistance at zero current and the second order current coefficient of resistance from the measurements by linear regression.

33. The apparatus of claim 31, wherein the parametric equation further comprises a temperature dependency cofactor, the cofactor including a unity constant corresponding to a fixed reference temperature added to a first order temperature coefficient multiplied by a change in temperature plus a second order temperature coefficient times the square of the change in temperature.

34. The apparatus of claim 33, wherein the means to determine coefficients is configured to determine the first order temperature coefficient and the second order temperature coefficient from the measurements by linear regression.

35. The apparatus of claim 31, wherein the resistive DUT comprises an equivalent circuit of two end elements in series combination with a body element, wherein the overall dimension of the resistive DUT has a length L, a width W, and an area L×W.

36. The apparatus of claim 35, wherein the body element of the resistive DUT is a poly-silicon sheet resistor on a Si substrate.

37. The apparatus of claim 36, wherein a resistance of the body element of the DUT is a function of a sheet resistance of the sheet, the source current, a width of the sheet layer, a length of the sheet layer, and temperature.

38. The apparatus of claim 37, wherein when the end elements each have a sheet dimension area of ΔW×ΔL, the end elements have a resistance Rend equal to an end resistance at zero source current bias R0 divided by (W−ΔW).

39. The apparatus of claim 38, wherein the body resistance Rbody is equal to a body sheet resistance Rsh multiplied by (L−ΔL) and divided by (W−ΔW).
